(19) United States
(12) Patent Application Publication
(10) Pub. No.: US 2007/0063308 A1
(43) Pub. Date: Mar. 22, 2007

(54) Integrated circuit with partly silicidated silicon layer

(75) Inventors: Hendrik Hubertus Van Der Meer, Nijmegen (NL); Wilhelmus Cornelis Maria Peters, Nijmegen (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS N.V., Eindhoven (NL)

(21) Appl. No.: 10/577,102

(22) PCT Filed: Oct. 14, 2004
(86) PCT No.: PCT/IB04/52085

§ 371 Date: Apr. 25, 2006

(30) Foreign Application Priority Data
Oct. 29, 2003 (EP) 03104002.5

(51) Int. Cl. H01L 29/00

(52) U.S. Cl. 257/506

(57) ABSTRACT

The integrated circuit (1) comprises an electric device (2) such as a resistor which comprises a first silicon layer (120) having a silicidated part (122) and a non-silicidated part (123), and a further electric device (3) such as, e.g. a capacitor, a field effect transistor or a non-volatile memory gate stack. The further electric device (3) comprises a dielectric layer (130) having a dielectric layer thickness (D). The non-silicidated part (123) of the electric device (2) is covered by a further dielectric layer (131) having the dielectric layer thickness (D), the silicidated part (122) is not covered by the further dielectric layer (131). Such an integrated circuit (1) may be formed by a method according to invention which involves a reduced number of lithography steps.

The invention relates to an integrated circuit (IC) comprising an electric device comprising a first silicon layer having a silicidated part and a non-silicidated part.

The invention further relates to a method for manufacturing such an IC.

State-of-the art ICs often comprise a silicon layer with a silicidated part for e.g. electrically contacting the silicon layer by a metal contact and a non-silicidated part. The non-silicidated part may constitute a semiconducting layer in e.g. a field effect transistor (FET) or a bipolar transistor, or it may constitute a part of a resistor which due to the relatively low conductivity of non-silicidated silicon as compared to that of silicidated silicon may mainly determine the resistance value of the resistor.

An embodiment of a method for manufacturing such an IC is disclosed in WO 00/10198. A layer of silicon nitride and a layer of silicon oxide are subsequently deposited on a crystalline silicon body with shallow trench insulation and poly silicon ridges. The layer of silicon nitride and the layer of silicon oxide are patterned by lithography to expose the parts to be silicidated whereas the parts not to be silicidated are covered by these layers. A titanium layer is deposited and thermally treated, so that it reacts with the exposed silicon to form silicide in the silicidated part whereas in the part covered by the layer of silicon nitride and the layer of silicon oxide the titanium does not react with the silicon. The patterned layer of silicon nitride and the patterned layer of silicon oxide form a so-called silicidation protection mask, also referred to as SIPROT mask. The titanium which did not reacted with silicon is removed.

It is a disadvantage of the known IC that providing the non-silicidated regions requires a dedicated lithography step which increases the manufacturing costs.

It is an object of the invention to provide an IC which may be manufactured without a dedicated lithography step for providing the non-silicidated regions.

According to the invention this object is realized in that the IC further comprises a further electric device with a dielectric layer having a dielectric layer thickness, and in that the non-silicidated part of the electric device is covered by a further dielectric layer having the dielectric layer thickness whereas the silicidated part is not covered by the further dielectric layer.

In normal IC technology forming the dielectric layer of the further electric device and forming the SIPROT mask each require a dedicated lithography step. According to the invention instead of these two lithography steps a single photolithography step may be used. To this end a layer of a dielectric material may be provided which after a single lithography step is patterned to simultaneously form the dielectric layer of the further electric device and the further dielectric layer of the electric device which serves as a SIPROT mask. Because the dielectric layer and the further dielectric layer are obtained from the same layer of dielectric material, they have the same layer thickness.

According to the invention the electric device and the further electric device are not mutual replicas but different devices such as e.g. a resistor, a FET, a bipolar transistor, a capacitor and/or a non-volatile memory cell. The silicidated part may be formed by depositing a metal layer, such as e.g. titanium, cobalt or titanium-cobalt (Pt, Ni) and carrying out a heat treatment, whereby the metal reacts with the silicon in contact with the metal layer. The invention is not restricted to a particular metal.

Many ICs have a resistor with a resistance value which is controlled by partly silicidating a layer of silicon. These partly silicidation may be done by a method according to the invention. In this case the electric device may comprise a resistor. The silicidated part of the resistor may comprise a first contact area and a second contact area, the non-silicidated part separating the first contact area from the second contact area.

The resistor may be formed in a dedicated layer of silicon which may be provided on a main surface of a prefabricated IC during the manufacturing. Alternatively, the resistor may be formed in a part of a silicon wafer itself. The silicon wafer may be doped to adjust the conductivity of the resistor and to define the shape of the resistor. The corresponding doping may be performed simultaneously with the doping of another region of the IC such as, e.g. the source and/or drain region of a FET or the collector and/or the base of a bipolar transistor.

The further electric device may comprise a second silicon layer at least partly covering the dielectric layer. The further dielectric layer of the electric device may be at least partly covered by a third silicon layer. To this end a layer of silicon may be provided which after a single lithography step is patterned to simultaneously form the second silicon layer and the third silicon layer. The second silicon layer and the third silicon layer may be used as a hard mask in patterning the dielectric layer and the further dielectric layer, respectively. As a result of this method of manufacturing the second silicon layer and the third silicon layer have the same layer thickness.

The second silicon layer and the third silicon layer may be silicidated, e.g. for allowing for electrically contacting the second silicon layer and/or the third silicon layer. The third silicon layer may be electrically connected to ground potential.

The third silicon layer may have a sidewall being provided with an insulating sidewall spacer. The insulating sidewall spacer may reduce the occurrence of so-called silicide bridging. Silicide bridging is a process in which an electrical short circuit between the silicidated part of the first silicon layer and the third silicon layer is obtained by a silicide layer formed during heating the metal film forming the silicide.

The further electric device may comprise a capacitor having a capacitor dielectric layer and a capacitor electrode layer, the dielectric layer comprising the capacitor dielectric layer, the second silicon layer comprising the capacitor electrode layer.

The further electric device may comprise a FET having a gate dielectric layer and a gate electrode layer, the dielectric layer comprising the gate dielectric layer, the second silicon layer comprising the gate electrode layer. According to the invention the gate dielectric layer and the further dielectric layer may be formed by a single lithography step. The second silicon layer and the third silicon layer may be formed in the same step.

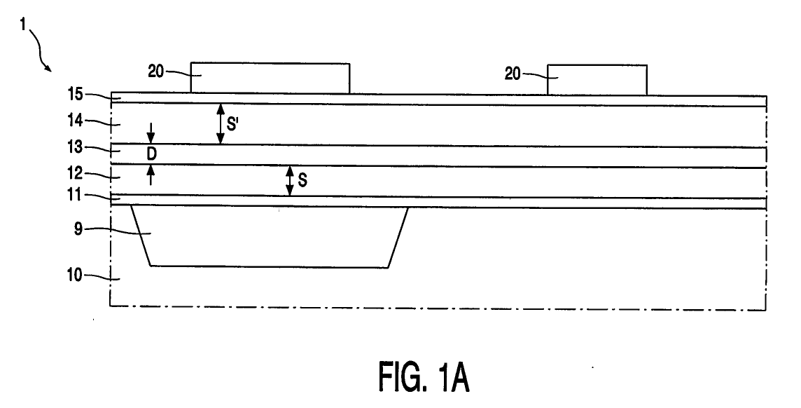

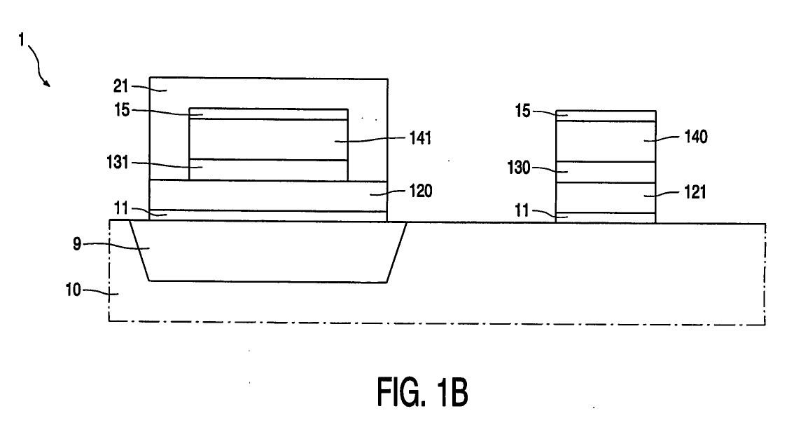

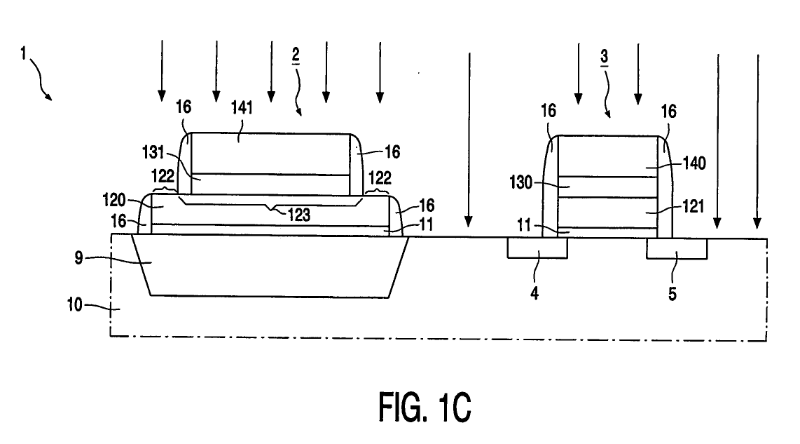

The further electric device may comprise a non-volatile memory cell having a floating gate layer, an intergate dielectric layer and a control gate layer. The integrate dielectric layer electrically insulates the floating gate from the control gate. The floating gate layer may be composed of silicon, the dielectric layer may comprise the intergate dielectric layer and the second silicon layer may comprise the control gate layer. The memory cell may have a stacked gate, i.e. the floating gate layer, the integrate dielectric layer and the control gate layer are stacked as depicted in FIG. 1C. Alternatively, the memory cell may have a so-called overlay structure in which the integrate dielectric layer and the control gate dielectric layer overlay and partly enclose the floating gate. In a method for manufacturing such an IC, before providing the layer of the dielectric material and the silicon layer a further layer may be provided on top of which the layer of the dielectric material and the silicon layer are provided. Using a single lithography step the layer of silicon may be patterned to simultaneously form the second silicon layer and the third silicon layer. The second silicon layer and the third silicon layer may be used as a hard mask to pattern the layer of dielectric material to simultaneously form the dielectric layer and the further dielectric layer. The first silicon layer may be formed from the further layer of silicon using a second lithography step and a material removal step such as, e.g., an etching step. The floating gate may be formed from the further layer of silicon as well, such that the number of layers to be applied is relatively small. In this case the first silicon layer and the floating gate layer have the same thickness. The floating gate and the first silicon layer may be formed simultaneously. The floating gate and the first silicon layer may be patterned prior to providing the layer of the dielectric material and the layer of silicon, if present.

The further electric device may comprise a bipolar transistor having a base region and an emitter layer contacting the base region in an emitter-base contact area, a part of the emitter layer comprising the emitter-base contact area being delimited by an opening in the dielectric layer, the emitter layer being constituted by the second silicon layer. In this case the dielectric layer having this opening may be formed simultaneously with the further dielectric layer. The emitter layer may be formed simultaneously with the second silicon layer. The base of the bipolar transistor may have been formed already in a dedicated layer of silicon which may be provided on a main surface of the prefabricated IC during an earlier step of the manufacturing.

The IC may further comprise an additional electric device having an additional dielectric layer which has the dielectric layer thickness and which is not a mere replica of the electric device or the further electric device. In this case the IC comprises at least three different types of electric devices which each have a dielectric layer having the same layer thickness.

The IC may further comprise a fourth electric device having a fourth dielectric layer which has the dielectric layer thickness and which is not a mere replica of the electric device, the further electric device or the additional electric device. In this case the IC comprises at least four different types of electric devices which each have a dielectric layer having the same layer thickness.

The IC may further comprise a fifth electric device having a fifth dielectric layer which has the dielectric layer thickness and which is not a mere replica of the electric device, the further electric device, the additional electric device or the fourth electric device. In this case the IC comprises at least five different types of electric devices which each have a dielectric layer having the same layer thickness.

The dielectric layer, the further dielectric layer, the additional dielectric layer, the fourth dielectric layer, if present, and the fifth dielectric layer, if present, may be simultaneously formed from the same layer of dielectric material using one lithography step. The electric device, the further electric device, the additional electric device, the fourth electric device, if present, and the fifth electric device, if present, may be selected from e.g. a resistor, a capacitor, a FET, a memory cell and/or a bipolar transistor as described above.

The method of manufacturing an integrated circuit according to the invention comprises the steps of providing a prefabricated integrated circuit having the first silicon layer, providing a layer of a dielectric material having the dielectric layer thickness, patterning the layer of the dielectric material to simultaneously form the dielectric layer and the further dielectric layer, and forming the silicidated part.

Because of the step of patterning the layer of the dielectric material to simultaneously form the dielectric layer and the further dielectric layer, a single lithography step suffices whereas in the prior art two lithography steps were required.

According to the invention the provided prefabricated integrated circuit having the first silicon layer may have the first silicon layer patterned in its final shape. Alternatively and still within the scope of the invention, the first silicon layer may be comprised in a layer of silicon which may be patterned to form the first silicon layer or which may be defined in other ways such as e.g. doping a part of the silicon substrate.

When the IC comprises the second silicon layer and the third silicon layer the method according to the invention may further comprise the steps of proving a layer of silicon having the second silicon layer thickness, and patterning the layer of silicon to simultaneously form the second silicon layer and the third silicon layer.

Because of the step of patterning the layer of silicon to simultaneously form the second silicon layer and the third silicon layer these two layers may be obtained using only one lithography step. This may be the same lithography step used for patterning the layer of the dielectric material to simultaneously form the dielectric layer and the further dielectric layer.

The, e.g. silicidated, second silicon layer and/or the silicidated third silicon layer may be used as local interconnect layer. In this case an additional dedicated step of forming the local interconnects may be saved.

These and other aspects of the IC according to the invention and the method of fabricating such an IC will be further elucidated and described with reference to the drawings, in which:

FIGS. 1A-1C shows a cross section of an embodiment of the integrated circuit at various stages of the manufacturing process;

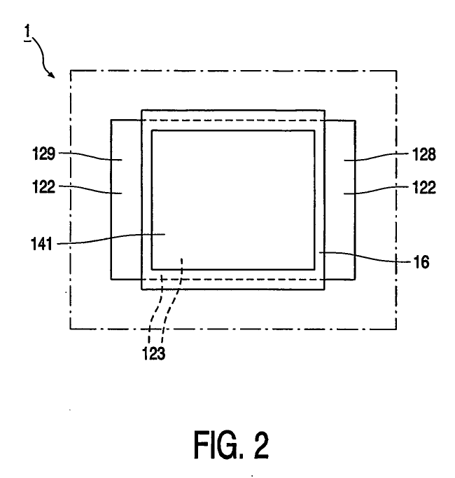

FIG. 2 shows a top view of a portion of the integrated circuit of FIG. 1C;

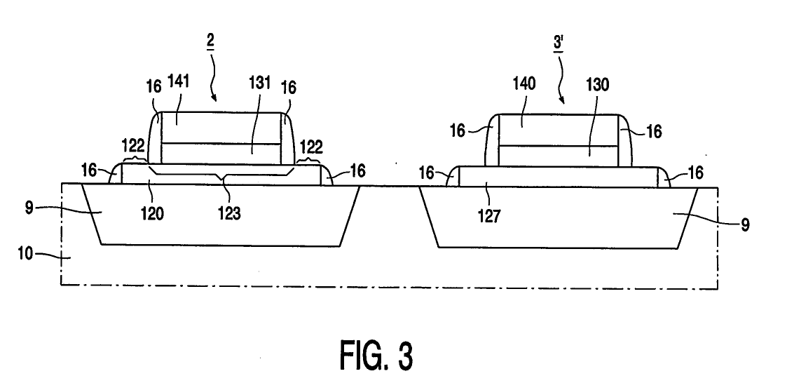

FIG. 3 shows a cross section of another embodiment of the integrated circuit;

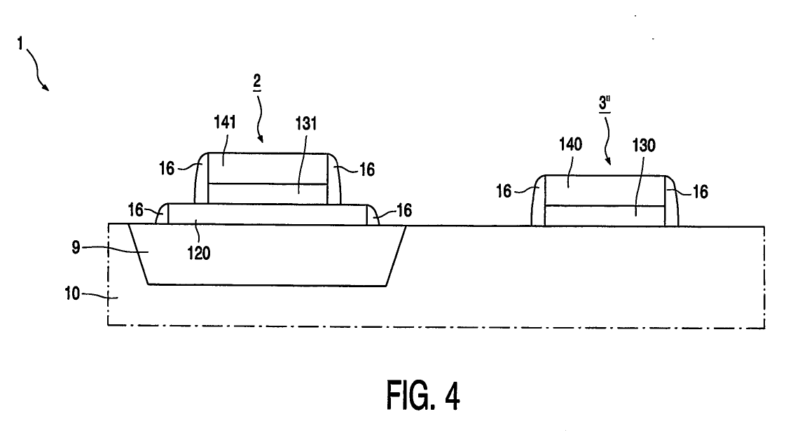

FIG. 4 shows a cross section of yet another embodiment of the integrated circuit;

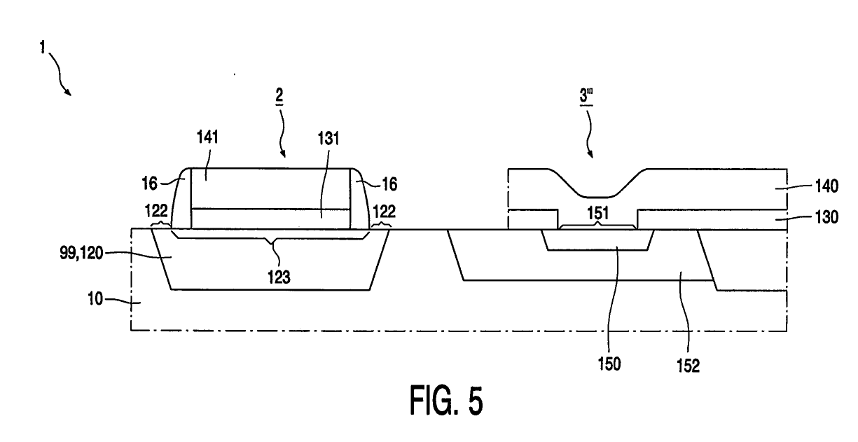

FIG. 5 shows a cross section of yet another embodiment of the integrated circuit

The Figures are not drawn to scale. In general, identical components are denoted by the same reference numerals.

FIG. 1A shows a prefabricated integrated circuit 1 comprising a substrate 10 which may be, e.g. a silicon wafer. The substrate 10 has a field isolation zone 9 which is a shallow trench isolation. Alternatively, the field isolation zone 9 may be obtained by LOCOS. The substrate 10 is provided on a main surface thereof with a dielectric layer 11 of, e.g. silicon oxide or silicon nitride. The dielectric layer 11 and all other dielectric layers of the IC described below may be composed of a stack of dielectric layers. The dielectric layer 11 is provided with a silicon layer 12 having a layer thickness S. Here and in the remainder of the application thickness refers to a dimension perpendicular to the main surface of substrate 10, unless stated otherwise. From silicon layer 12 the first silicon layer 120 will be formed later on.

On the prefabricated integrated circuit 1 thus obtained a layer 13 of a dielectric material having the dielectric layer thickness D is provided of which the dielectric layer 130 and the further dielectric layer 131 will be formed later on. Subsequently a layer 14 of silicon having the second silicon layer thickness S′ is provided of which layer 14 the second silicon layer 140 and the third silicon layer 141 will be formed later on. On top of layer 14 a capping layer 15 of e.g. silicon nitride may be formed which will serve as a hard mask in a later process step.

Subsequently, a mask 20 shown in FIG. 1A is formed by, e.g., photo lithography, electron beam lithography or another lithography technique. The mask 20 covers those parts of the stack comprising layers 11, 12, 13, 14 and 15 which comprise the second silicon layer 140, the third silicon layer 141, the dielectric layer 130 and the further dielectric layer 131 to be formed later on, whereas the remainder of the stack is exposed. In a material removal step such as, e.g., an etching step the exposed parts of capping layer 15 are removed. After this step mask 20 may be removed. Subsequently, the parts of layer 14 thus exposed are removed to pattern the layer 14 to simultaneously form the second silicon layer 140 and the third silicon layer 141. The remaining parts of capping layer 15 may be used as a hard mask. Then, in another material removal step the parts of layer 13 thus exposed are removed to pattern the layer 13 to simultaneously form the dielectric layer 130 and the further dielectric layer 131. The remaining parts of capping layer 15 may be used as a hard mask in this material removal step as well.

In a next step a mask 21 shown in FIG. 1B is formed by, e.g., photo lithography, electron beam lithography or another lithography technique. The mask 21 covers those parts of layer 12 of which the first silicon layer 120 will be formed later on whereas remainder of the pre-fabricated IC is exposed. In another material removal step the exposed parts of layer 12 are removed to pattern the layer 12 to simultaneously form the first silicon layer 120 and a floating gate layer 121. Then, the parts of layer 11 thus exposed are removed by another material removal treatment The pre-fabricated IC thus obtained is shown in FIG. 1B. After these steps mask 20 may be removed. Alternatively, mask 21 may be removed after patterning layer 12 but before patterning layer 11.

The capping layer 15 may then be removed by a material removal treatment, and a layer of a dielectric material may be formed which is subsequently etched to form insulating sidewall spacers 16 against sidewalls of the first silicon layer 120, against sidewalls of a stack formed by the further dielectric layer 131 and the third silicon layer 141, and against a gate stack 3 comprising the floating gate layer 121, the dielectric layer 130 and the second silicon layer 140.

Before and/or after the formation of the sidewall spacers 16 against gate stack 3, a source region 4 and drain region 5 may be formed by ion-implantation. The further electric device thus obtained is a non-volatile memory cell having the floating gate layer 121, an intergate dielectric layer constituted by the dielectric layer 130, and a control gate layer constituted by the second silicon layer 140.

The floating gate layer 121 is composed of silicon having the same layer thickness S as the first silicon layer 120. The intergate dielectric layer has the same layer thickness D as the further dielectric layer 131. The control gate layer has the same layer thickness S′ as the third silicon layer 141.

In a subsequent step a metal layer of, e.g. Ti, is deposited as indicated by the arrows in FIG. 1C and the pre-fabricated IC thus obtained is heated such that those parts of the metal layer which are in direct contact with silicon form a silicide. Those parts of the metal film which did not react with silicon to form silicide are subsequently removed.

As a result the electric device 2 which is a resistor and which is composed of the first silicon layer 120, has a silicidated part 122 and a non-silicidated part 123. The non-silicidated part 123 of the electric device 2 is covered by the further dielectric layer 131 having the dielectric layer thickness D. The silicidated part 122 is not covered by the further dielectric layer 131.

The second silicon layer 140 and the third silicon layer 141 are silicidated and may be contacted to be metal lines, not shown. The third silicon layer 141 may be contacted to ground potential.

The silicidated part 122 of the resistor may comprise a first contact area 128 and a second contact area 129. The non-silicidated part 123 separates the first contact area 128 from the second contact area 129, as is shown in FIG. 2. The sidewall spacers 16 may cover the edges of the non-silicidated part 123 as shown in FIG. 2. The first contact area 128 and the second contact area 129 may be provided with metal contacts to electrically contact the resistor by an electrical input line and an electrical output line.

In the embodiment shown in FIG. 3 the integrated circuit 1 comprises a further electric device 3′ which is a capacitor having a capacitor dielectric layer and a capacitor electrode layer. The electric device is a resistor 2 similar to the one described above. The method of manufacturing is similar to the one described above: The substrate 10 has at least two field isolation zones 9 similar to the one described above. The substrate 10 is provided on a main surface thereof with a silicon layer 12 having a layer thickness S on top of which a layer 13 of a dielectric material having the dielectric layer thickness D is provided. Subsequently a layer 14 of silicon having the second silicon layer thickness S′ is provided On top of layer 14 a capping layer 15 of e.g. silicon nitride may be formed which will serve as a hard mask in a later process step.

Subsequently, a mask is formed lithographically covering those parts of the stack comprising layers 12, 13, 14 and 15 which comprise the second silicon layer 140, the third silicon layer 141, the dielectric layer 130 and the further dielectric layer 131 to be formed later on, whereas the remainder of the stack is exposed. In a sequence of material removal steps capping layer 15, if present, is patterned, layer 14 is patterned to simultaneously form the second silicon layer 140 and the third silicon layer 141, and layer 13 is patterned to simultaneously form the dielectric layer 130 and the further dielectric layer 131.

In an additional lithography step a mask may be formed covering those parts of layer 12 of which the first silicon layer 120 and a further capacitor electrode 127 will be formed later on whereas remainder of the pre-fabricated IC is exposed. In another material removal step the exposed parts of layer 12 are removed to pattern the layer 12 to simultaneously form the first silicon layer 120 and the further capacitor electrode 127. The capping layer 15 may then be removed by a material removal treatment, and a layer of a dielectric material may be formed which is subsequently etched to form insulating sidewall spacers 16 shown in FIG. 3.

The further electric device thus obtained is capacitor having a capacitor dielectric layer which is constituted by the dielectric layer 130 and a capacitor electrode layer which is constituted by the second silicon layer 141. The further capacitor electrode 127 is composed of silicon having the same layer thickness S as the first silicon layer 120. The capacitor dielectric layer has the same layer thickness D as the further dielectric layer 131. The capacitor electrode layer has the same layer thickness S′ as the third silicon layer 141.

In a subsequent step a metal layer of, e.g. Ti, is deposited and the pre-fabricated IC thus obtained is heated such that those parts of the metal layer which are in direct contact with silicon form a silicide. Those parts of the metal film which did not react with silicon to form silicide are subsequently removed.

As a result the electric device 2 which is a resistor and which is composed of the first silicon layer 120, has a silicidated part 122 and a non-silicidated part 123. The non-silicidated part 123 of the electric device 2 is covered by the further dielectric layer 131 having the dielectric layer thickness D. The silicidated part 122 is not covered by the further dielectric layer 131.

The second silicon layer 140, the third silicon layer 141 and the exposed parts of the further capacitor electrode 127 are silicidated and may be contacted to be metal lines, not shown. The third silicon layer 141 may be contacted to ground potential.

In the integrated circuit 1 shown in FIG. 4 the electric device 2 is a resistor similar to the one described above and the further electric device 3″ comprises a field effect transistor (FET) having a gate dielectric layer, which is constituted by the dielectric layer 130, and a gate electrode layer, which is constituted by the second silicon layer 140. The dielectric layer 130 and the further dielectric layer 131 are obtained by simultaneously patterning a layer 13 of dielectric material and the second silicon layer 140 and the third silicon layer 141 are obtained by simultaneously patterning a layer 14 of silicon analogously to the ways described above.

In the embodiment shown in FIG. 5 the further electric device 3 comprises a bipolar transistor having a base region 150 and an emitter layer contacting the base region 150 in an emitter-base contact area 151. A part of the emitter layer comprising the emitter-base contact area 151 is delimited by an opening in the dielectric layer 130. The emitter layer is constituted by the second silicon layer 140. The IC 1 shown in FIG. 5 may be obtained as follows: The silicon substrate 10 is provided with implant region 99 defining the first silicon layer 120 and with implant region 152 defining the collector of the bipolar transistor 3′″. The implant region may be p-type or n-type. Inside the implant region 152 the base is formed by means of another implant. The base is provided with the layer 13 of dielectric material. On top of the base region 150 and of layer 120 a layer of dielectric material is provided which is patterned to define an opening at the position of the emitter-base contact area. At this opening the base region 150 is exposed. The prefabricated IC is then provided with a layer of silicon which contacts the base layer 150 inside the opening. The layer of silicon is then patterned to simultaneously form the second silicon layer 130 constituting the emitter layer and the third silicon layer 131. Subsequently, the layer of dielectric material is patterned to expose parts 122 of the first silicon layer 120 which are to be silicidated. Then the metal film is provided and the silicidated regions 122 are formed. The emitter layer may be silicidated in the same step as well. In summary, the integrated circuit 1 comprises an electric device 2 such as a resistor which comprises a first silicon layer 120 having a silicidated part 122 and a non-silicidated part 123, and a further electric device 3 such as, e.g. a capacitor, a field effect transistor or a non-volatile memory gate stack. The further electric device 3 comprises a dielectric layer 130 having a dielectric layer thickness D. The non-silicidated part 123 of the electric device 2 is covered by a further dielectric layer 131 having the dielectric layer thickness D, the silicidated part 122 is not covered by the further dielectric layer 131. Such an integrated circuit 1 may be formed by a method according to invention which involves a reduced number of lithography steps.

The IC 1 may comprise a resistor shown in any of the FIGS. 1C, 2, 3, 4, and/or 5, and/or a memory cell shown e.g. in FIG. 1C, and/or a capacitor shown in FIG. 3, and/or a FET shown e.g. in FIG. 4, and/or a bipolar transistor shown e.g. in FIG. 5.

It should be noted that the above-mentioned embodiments illustrate rather than limit the invention, and that those skilled in the art will be able to design many alternative embodiments without departing from the scope of the appended claims. In the claims, any reference signs placed between parentheses shall not be construed as limiting the claim. The word “comprising” does not exclude the presence of other elements or steps than those listed in a claim. The word “a” or “an” preceding an element does not exclude the presence of a plurality of such elements.

1. Integrated circuit (1) comprising:
an electric device (2) comprising a first silicon layer (120) having a silicidated part (122) and a non-silicidated part (123), and
a further electric device (3), the further electric device comprising a dielectric layer (130) having a dielectric layer thickness (D),
wherein the non-silicidated part (123) of the electric device is covered by a further dielectric layer (131) having the dielectric layer thickness (D), the silicidated part (122) not being covered by the further dielectric layer (131).

2. Integrated circuit (1) as claimed in claim 1, wherein the electric device (2) comprises a resistor.

3. Integrated circuit (1) as claimed in claim 2, wherein the silicidated part (122) of the resistor comprises a first contact area (128) and a second contact area (129), the non-silicidated part (123) separating the first contact area (128) from the second contact area (129).

4. Integrated circuit (1) as claimed in claim 1, wherein the dielectric layer (130) of the further electric device (3) is at least partly covered by a second silicon layer (140) having a second silicon layer thickness (S′), the further dielectric layer (131) of the electric device (2) being at least partly covered by a third silicon layer (141) having the second silicon layer thickness (S′).

5. Integrated circuit (1) as claimed in claim 4, wherein the second silicon layer (140) and the third silicon layer (141) are silicidated.

6. Integrated circuit (1) as claimed in claim 4, wherein the third silicon layer (141) has a sidewall being provided with an insulating sidewall spacer (16).

7. Integrated circuit (1) as claimed in claim 4, wherein the further electric device (3) comprises a capacitor having a capacitor dielectric layer and a capacitor electrode layer, the dielectric layer (130) comprising the capacitor dielectric layer, the second silicon layer (140) comprising the capacitor electrode layer.

8. Integrated circuit (1) as claimed in claim 4, wherein the further electric device (3) comprises a field effect transistor having a gate dielectric layer and a gate electrode layer, the dielectric layer (130) comprising the gate dielectric layer, the second silicon layer (140) comprising the gate electrode layer.

9. Integrated circuit (1) as claimed in claim 4, wherein the further electric device (3) comprises a non-volatile memory cell having a gate stack comprising a floating gate layer (121), an intergate dielectric layer and a control gate layer, the floating gate layer (121) being composed of silicon and having a thickness (S) which is identical to that of the first silicon layer (120), the dielectric layer (130) comprising the intergate dielectric layer, the second silicon layer (140) comprising the control gate layer.

10. Integrated circuit (1) as claimed in claim 4, wherein the further electric device (3) comprises a bipolar transistor having a base region (150) and an emitter layer contacting the base region (150) in an emitter-base contact area (151), a part of the emitter layer comprising the emitter-base contact area (151) being delimited by an opening in the dielectric layer (130), the emitter layer being constituted by the second silicon layer (140).

11. A method of manufacturing an integrated circuit (1) as claimed in claim 1, the method comprising the steps of:
providing a prefabricated integrated circuit having the first silicon layer (120),
providing a layer (13) of a dielectric material having the dielectric layer thickness (D),
patterning the layer (13) of the dielectric material to simultaneously form the dielectric layer (130) and the further dielectric layer (131), and
forming the silicidated part (122).

12. A method as claimed in claim 11, wherein the dielectric layer (130) of the further electric device (3) is at least partly covered by a second silicon layer (140) having a second silicon layer thickness (S′), the further dielectric layer (131) of the electric device (2) being at least partly covered by a third silicon layer (141) having the second silicon layer thickness (S′), the method further comprising the steps of:
providing a layer (14) of silicon having the second silicon layer thickness (S′), and
patterning the layer (14) of silicon to simultaneously form the second silicon layer (140) and the third silicon layer (141).

13. A method as claimed in claim 12, wherein the third silicon layer (141) has a sidewall being provided with an insulating sidewall spacer (16), the method further comprising the step of providing the sidewall spacers (16).
